(19) United States
(12) Patent Application Publication
(10) Pub. No.: US 2015/0303200 A1
(43) Pub. Date: Oct. 22, 2015

(54) SEMICONDUCTOR DEVICE AND METHOD FOR MANUFACTURING SAME

(71) Applicant: PS4 LUXCO S.A.R.L., Luxembourg (LU)

(72) Inventor: Kazuyoshi Yuki, Tokyo (JP)

(21) Appl. No.: 14/648,227

(22) PCT Filed: Sep. 25, 2013
(86) PCT No.: PCT/JP2013/075894

§ 371 Date: May 28, 2015

(30) Foreign Application Priority Data
Nov. 28, 2012 (JP) 2012-259484

(51) Int. Cl. H01L 27/108; H01L 29/78; H01L 29/66; H01L 29/49; H01L 29/06; H01L 21/02; H01L 21/311; H01L 21/768; H01L 21/285; H01L 29/423; H01L 23/535

(52) U.S. Cl. CPC H01L 27/10823; H01L 27/10876; H01L 29/4236; H01L 29/7833; H01L 27/10852; H01L 27/10814; H01L 29/66575; H01L 29/4966; H01L 23/535; H01L 21/02186; H01L 21/31111; H01L 21/76897; H01L 21/28568; H01L 29/0649

(57) ABSTRACT

A semiconductor device comprising: a silicon substrate; an embedded gate electrode groove provided in the silicon substrate; a gate insulating film provided on the wall inside the embedded gate electrode groove; an embedded gate electrode provided on the gate insulating film so as to be installed inside the embedded gate electrode groove, the embedded gate electrode, having a first portion having a titanium nitride film and a first metal film thereon, and a second portion having a single-layer titanium nitride film; and a contact plug electrically connected to the first metal film constituting the first portion of the embedded gate electrode.

### TECHNICAL FIELD

The present invention relates to a semiconductor device and a method for manufacturing the same.

### BACKGROUND ART

Transistors provided with embedded gate electrodes are conventionally used in memory cell regions of DRAMs (Dynamic Random Access Memory) and the like. These transistors comprise a gate insulating film and an embedded gate electrode provided successively on the inner walls of an embedded gate electrode groove excavated downward from the main surface of an active region, and a source and a drain provided on both sides, sandwiching the embedded gate electrode groove, within the active region. When the transistor is in the ON state, a channel is formed in the active region between the source and the drain along the embedded gate electrode groove.

Patent literature article 1 (Japanese Patent Kokai 2011-192800), patent literature article 2 (Japanese Patent Kokai 2011-159760) and patent literature article 3 (Japanese Patent Kokai 2012-84738) disclose a laminated film comprising a titanium nitride film (a barrier film) and a tungsten film formed by CVD, serving as the material for the embedded gate electrode. A reduction in the resistance of the embedded gate electrode can be achieved by employing such a laminated film.

### Patent Literature

Patent literature article 1: Japanese Patent Kokai 2011-192800

Patent literature article 2: Japanese Patent Kokai 2011-159760

Patent literature article 3: Japanese Patent Kokai 2012-84738

### SUMMARY OF THE INVENTION

### Problems to Be Resolved by the Invention

Miniaturization of semiconductor devices has progressed in recent years, and the line width of the embedded gate electrode has been reduced to approximately 20 nm. In a semiconductor device having such dimensions, if a laminated film comprising a titanium nitride film and a tungsten film is used as the material for the embedded gate electrode, the titanium nitride film, which is a barrier film, must be deposited to a thickness of at least 5 nm. However, if the thickness of the titanium nitride film is 5 nm, then because the 5 nm titanium nitride film is deposited on each inner side surface of the embedded gate electrode groove, the total film thickness is 10 nm, and the thickness of the tungsten film in the embedded gate electrode groove is approximately 10 nm. If, in this way, the thicknesses of the titanium nitride film and the tungsten film in the embedded gate electrode groove are similar, it is difficult for the resistance of the embedded gate electrode to be made sufficiently low. Accordingly, it is conceivable to use as the material for the embedded gate electrode a single-layer film of titanium nitride, formed using a deposition method having good coverage and imparting a low-resistance characteristic.

(1) However, when a contact plug connected to an embedded gate electrode comprising a single-layer film of titanium nitride is formed, a problem arises in that the deposition of etching reactants (for example titanium fluoride) (reattachment of etching reactants) when the contact hole is being formed has the effect of markedly increasing the contact resistance between the embedded gate electrode and the contact plug.

(2) Further, problems of lost-contact failure arise when a contact plug connected to the embedded gate electrode is being formed. Lost-contact failure will now be described with reference to FIG. 3. FIG. 3 is a cross-sectional view illustrating a peripheral circuit region in a conventional DRAM. As illustrated in FIG. 3, a first transistor Tr1 and a second transistor Tr2 are provided in the peripheral circuit region Impurity-diffused layers 53 are provided in active regions 1A demarcated by element isolation regions 9 in a silicon substrate 1, and contact plugs 55a and 55b are connected to the impurity-diffused layers 53. A contact plug 55c is connected to a gate electrode 54 of the first transistor Tr1. Further, an embedded gate electrode (word line) 23 extends from a memory cell region, which is not shown in the drawing, to within the element isolation region 9 in the peripheral circuit region, and a contact plug 55d is connected to the embedded gate electrode (word line) 23. The contact plug 55c is connected to a gate electrode of the second transistor Tr2 by way of a contact plug which is not shown in the drawing. The contact plugs 55a are connected to the impurity-diffused layer 53 of the first transistor Tr1 by way of contact plugs which are not shown in the drawing.

As illustrated in FIG. 3, in a conventional DRAM peripheral circuit region, the contact plugs 55a, 55b and 55c connected to the impurity-diffused layers 53 or the gate electrodes 54 are formed in such a way that their bottom surfaces are at the same height as the outermost surface of the silicon substrate 1, or are higher than the outermost surface of the silicon substrate 1. In contrast, the contact plug 55d connected to the embedded gate electrode 23 is formed in such a way that its bottom surface is lower than the outermost surface of the silicon substrate 1. Thus the aspect ratio of the contact hole for the contact plug 55d is greater than that of the contact holes for the contact plugs 55a, 55b and 55c. Therefore problems of lost-contact failure, whereby the embedded gate electrode 23 and the contact plug 55d do not connect to each other correctly, arise as a result of the diameter of the contact hole for the contact plug 55d becoming smaller than the target value, or as a result of the embedded gate electrode 23 being covered thickly by an interlayer insulating film. Meanwhile, if the etching time setting is increased in order to suppress such lost-contact failures, problems arise in that the diameters of the contact holes for the contact plugs 55a, 55b and 55c increase due to over-etching, and the contact plugs 55a, 55b and 55c come into contact with unintended conductive portions, this contact being manifested as a leak failure. The problem of lost-contact failure occurs as discussed hereinabove, and this problem is becoming more pronounced as miniaturization of semiconductor devices progresses.

The present invention was developed in order to resolve the abovementioned problems (1) and (2), and in the present invention, etching deposition of etching reactants during formation of the contact holes is suppressed, and the generation of lost-contact failures is suppressed. By this means the present invention provides a semiconductor device having an improved yield and improved device characteristics, and a method of manufacturing the same.

### Means of Overcoming the Problems

One mode of embodiment relates to a semiconductor device comprising:

a silicon substrate,

an embedded gate electrode groove provided in the silicon substrate,

a gate insulating film provided on an inner wall of the embedded gate electrode groove,

an embedded gate electrode which is provided on the gate insulating film in such a way as to fill the embedded gate electrode groove, and which comprises a first part comprising a titanium nitride film with a first metal film thereon, and a second part comprising a single-layer film of the titanium nitride film but not including the first metal film, and

a contact plug which is electrically connected to the first metal film which is a constituent of the first part of the embedded gate electrode.

Another mode of embodiment relates to a method of manufacturing a semiconductor device, comprising:

a step of forming an embedded gate electrode groove in a silicon substrate,

a step of forming a gate insulating film on an inner wall of the embedded gate electrode groove,

a step of forming a titanium nitride film on the gate insulating film in such a way as to fill the embedded gate electrode groove,

a step of etching back a portion of the titanium nitride film to cause its upper surface to recede,

a step of forming a first metal film on the receded upper surface of the titanium nitride film,

a step of forming a first part comprising the titanium nitride film and the first metal film by etching back the first metal film to cause its upper surface to recede,

a step of forming a second part comprising a single-layer film of the titanium nitride film by etching back the exposed part of the titanium nitride film to cause its upper surface to recede, and

a step of forming a contact plug which is electrically connected to the first metal film.

### Advantages of the Invention

Etching deposition that occurs when the contact holes are being formed can be suppressed, and the occurrence of lost-contact failures can be suppressed. It is consequently possible to provide a semiconductor device having an improved yield and improved device characteristics, and a method of manufacturing the same.

### BRIEF EXPLANATION OF THE DRAWINGS

FIG. 1 is a drawing illustrating a first example of a semiconductor device.

FIG. 2 is a drawing illustrating the first example of a semiconductor device.

FIG. 3 is a drawing illustrating a conventional semiconductor device.

FIG. 4 is a drawing illustrating a method of manufacturing the first example of a semiconductor device.

FIG. 5 is a drawing illustrating the method of manufacturing the first example of a semiconductor device.

FIG. 6 is a drawing illustrating the method of manufacturing the first example of a semiconductor device.

FIG. 7 is a drawing illustrating the method of manufacturing the first example of a semiconductor device.

FIG. 8 is a drawing illustrating the method of manufacturing the first example of a semiconductor device.

FIG. 9 is a drawing illustrating the method of manufacturing the first example of a semiconductor device.

FIG. 10 is a drawing illustrating the method of manufacturing the first example of a semiconductor device.

FIG. 11 is a drawing illustrating the method of manufacturing the first example of a semiconductor device.

FIG. 12 is a drawing illustrating the method of manufacturing the first example of a semiconductor device.

FIG. 13 is a drawing illustrating the method of manufacturing the first example of a semiconductor device.

FIG. 14 is a drawing illustrating the method of manufacturing the first example of a semiconductor device.

FIG. 15 is a drawing illustrating the method of manufacturing the first example of a semiconductor device.

FIG. 16 is a drawing illustrating the method of manufacturing the first example of a semiconductor device.

FIG. 17 is a drawing illustrating the method of manufacturing the first example of a semiconductor device.

FIG. 18 is a drawing illustrating the method of manufacturing the first example of a semiconductor device.

FIG. 19 is a drawing illustrating the method of manufacturing the first example of a semiconductor device.

FIG. 20 is a drawing illustrating the method of manufacturing the first example of a semiconductor device.

FIG. 21 is a drawing illustrating the method of manufacturing the first example of a semiconductor device.

FIG. 22 is a drawing illustrating the method of manufacturing the first example of a semiconductor device.

FIG. 23 is a drawing illustrating the method of manufacturing the first example of a semiconductor device.

FIG. 24 is a drawing illustrating the method of manufacturing the first example of a semiconductor device.

FIG. 25 is a drawing illustrating a method of manufacturing a second example of a semiconductor device.

### MODES OF EMBODYING THE INVENTION

A semiconductor device and a method of manufacturing the same, being examples in which the present invention has been applied, will now be described with reference to the drawings. These examples are specific examples illustrated to provide a more in-depth understanding of the present invention, and the present invention is not in any way restricted to these specific examples. Further, the same reference codes are assigned to the same members, and explanations thereof are omitted or simplified. Further, reference codes are omitted as appropriate for the same member. It should be noted that the drawings used in the following description are schematic, and the ratios between length, width and thickness, for example, in each drawing are not necessarily the same as would actually be the case, and in some cases the ratios between length, width and thickness, for example, are not consistent between the drawings. In the following example, conditions such as materials and dimensions that are shown specifically are merely shown by way of example.

(First Example)

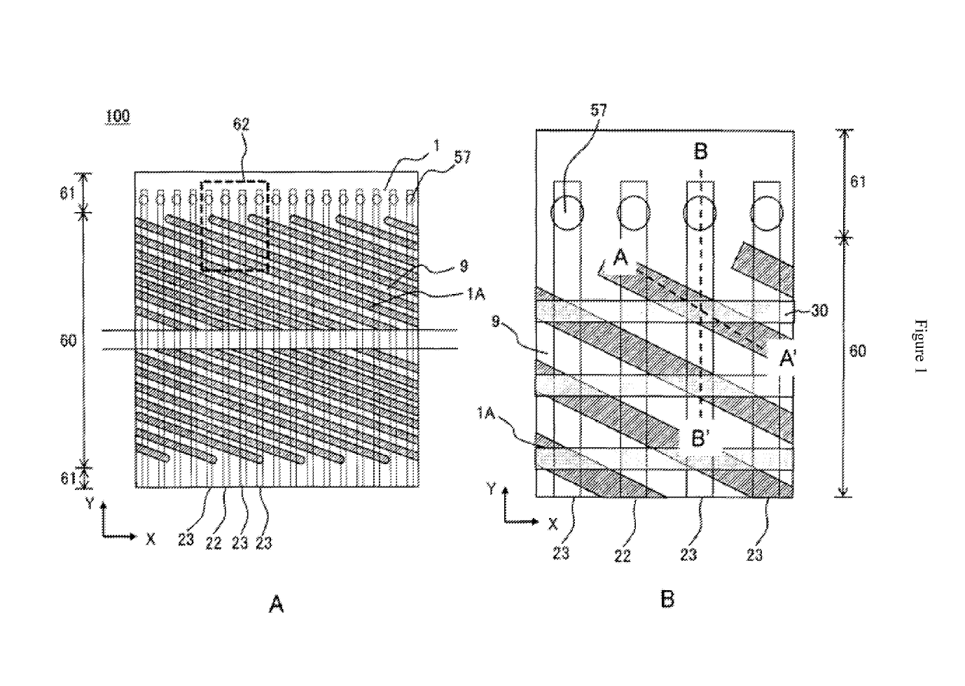

FIG. 1 is a plan view illustrating the configuration of a DRAM 100 according to this example, illustrating a memory cell region of the DRAM 100. FIG. 1A is a planar schematic diagram illustrating the arrangement of element isolation regions 9, active regions 1A, embedded gate electrodes 23 and embedded wiring lines for element isolation 22, in the DRAM 100, and FIG. 1B is an enlarged view of the part 62 enclosed by the dashed line in FIG. 1A. It should be noted that in FIG. 1 only the main structures are illustrated, in order to clarify the arrangement condition of the constituent elements.

As illustrated in FIG. 1, the DRAM 100 comprises a memory cell region 60 and peripheral regions 61 outside the memory cell region 60, in which drive transistors (which are not shown in the drawings) are disposed. The memory cell region 60 is provided with element isolation regions 9 (hereinafter referred to as ‘STIs (Shallow Trench Isolation) 9’) provided in a silicon substrate 1, and active regions 1A demarcated by the STIs 9. A plurality of embedded gate electrodes (word lines) 23 and a plurality of embedded wiring lines for element isolation 22 are provided in such a way as to extend in the Y-direction across the memory cell region 60 and the peripheral circuit regions 61.

The embedded gate electrodes 23 and the embedded wiring lines for element isolation 22 have the same structure but different functions. The embedded gate electrodes 23 function as the gate electrodes of the memory cells. The embedded wiring lines for element isolation 22 isolate adjacent elements (transistors) by being maintained at a certain electric potential. In other words, by maintaining the embedded wiring lines for element isolation 22 at a certain electric potential, parasitic transistors in the OFF state can be used to isolate adjacent elements on the same active region 1A. A plurality of bit lines 30 are disposed, with a certain spacing, in a direction (the X-direction in FIG. 1B) orthogonal to the embedded wiring lines 22. The embedded gate electrodes 23 and the embedded wiring lines 22 are each connected to contact plugs 57 in the peripheral circuit regions 61.

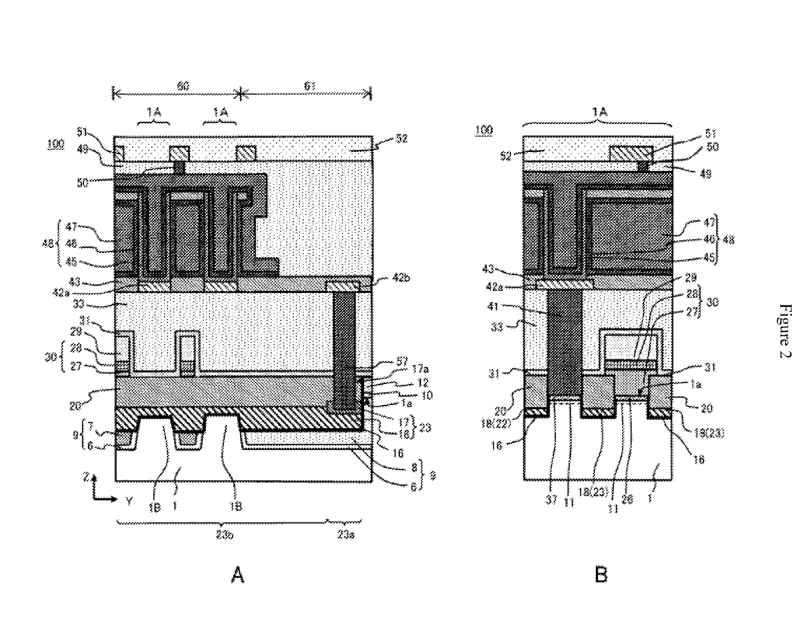

FIG. 2 is a cross-sectional view illustrating the configuration of the memory cell region in the DRAM 100 according to this example, where FIG. 2A is a cross-section through B-W in FIG. 1B and FIG. 2B is a cross-section through A-N in FIG. 1B. In the DRAM 100 in this example a silicon substrate is used as the silicon substrate which forms a base.

As illustrated in FIG. 2, the embedded gate electrodes (word lines) 23 cover a portion of the upper surfaces of the plurality of STIs 9 and the silicon substrate 1. Each memory cell is formed in a region in which the embedded gate electrodes 23 and the active regions 1A intersect. A plurality of memory cells are provided throughout the memory cell region, and capacitors 48 are connected to each memory cell by way of capacitor contact pads 42a. The capacitor contact pads 42a are disposed with a certain spacing within the memory cell region 60 in such a way that they do not overlap one another. It should be noted that, as illustrated in FIG. 1, the DRAM 100 in this example has a 6F2 cell arrangement (the F value is the minimum processing dimension) corresponding to a unit area in which the spacings in the X-direction and the Y-direction are respectively 3F and 2F.

As illustrated in FIG. 2, the DRAM 100 in this example is provided with embedded gate type transistors in which the embedded gate electrodes 23 functioning as gate electrodes are completely embedded in the silicon substrate 1. The embedded gate type transistors are provided in the active regions 1A which are surrounded by the STIs 9 which form element isolation regions in the silicon substrate 1. It should be noted that the STIs 9 comprise an insulating film (a silicon dioxide film) 6 and an insulating film (a silicon dioxide film 8 laminated onto a silicon nitride film 7, or a silicon dioxide film 8) which are laminated together in a groove in the silicon substrate 1. The embedded gate type transistors have a configuration comprising a gate insulating film 16 covering the inner walls of a groove provided in the active region 1A, a titanium nitride film 18 covering the upper surface portion and a portion of the side surface portions of the gate insulating film 16, a first impurity-diffused layer 26 forming one of the source and the drain, provided in a low-concentration impurity-diffused layer 11, and a second impurity-diffused layer 37 forming the other of the source and the drain. The low-concentration impurity-diffused layer 11 is provided in an upper portion of the active region 1A, excluding the region in which the gate insulating film 16 is provided, and is a layer in which an impurity is diffused, said impurity having the opposite conduction type to an electrically conductive impurity of which a large amount is contained in the silicon substrate 1. Further, the upper surface of the titanium nitride film 18 is covered by a silicon nitride film 20. The silicon nitride film 20 is provided in such a way as to protrude upward further than a main surface 1a of the silicon substrate 1, the upper surface of the silicon nitride film 20 being higher than the main surface 1a of the silicon substrate 1.

As illustrated in FIG. 2A, the embedded gate electrode 23 is provided in such a way that its outermost surface is in a position that is lower than the main surface 1a of the silicon substrate 1, and the embedded gate electrode 23 extends in a fixed direction (the Y-direction illustrated in FIG. 1) from the memory cell region 60 to the peripheral circuit region 61. The embedded gate electrode 23 is formed from a first part 23a comprising the titanium nitride film 18 and a tungsten film (first metal film) 17 provided on the titanium nitride film 18, and a second part 23b comprising a single-layer film of the titanium nitride film 18, but not including the tungsten film (first metal film) 17. It should be noted that the single-layer film of the titanium nitride film includes not only a single titanium nitride film having a uniform composition and formed using the same deposition method, but also includes, for example, laminated films comprising a plurality of titanium nitride films each having a different nitrogen content, and laminated films comprising a plurality of titanium nitride films each formed using different deposition methods.

The contact plug 57 is connected to the tungsten film 17 which is a constituent of the first part 23a, and is thereby electrically connected to the embedded gate electrode 23. The contact plug 57 is connected to a wiring line layer 42b. The side surface of the end portion of the embedded gate electrode 23 located in the peripheral circuit region 61 faces, with the interposition of the gate insulating film 16, a sacrificial film 10, which is a silicon dioxide film, and a lower-layer masking film 12, which is a silicon dioxide film. It should be noted that although the structure of the embedded wiring lines 22 is not illustrated in FIG. 2A, the embedded wiring lines 22 have the same structure as the embedded gate electrodes 23, and are connected to contact plugs by way of the tungsten film 17 which is a constituent of the first part.

As described hereinabove, in the semiconductor device in this example, the contact plug 57 is connected to the tungsten film 17 of the first part 23a. Therefore, when a contact hole 17a for the contact plug 57 is being formed, the tungsten film 17 is exposed in the bottom portion of the contact hole 17a. Therefore, when the contact hole 17a is being formed, it is possible to prevent etching deposition (reattachment of etching reactants) of etching reactants (for example titanium fluoride) resulting from reactions between the etching gas and the titanium nitride film 18 existing below the tungsten film 17. As a result, an increase in the contact resistance between the contact plugs 57 and the embedded gate electrodes 23 and embedded wiring lines 22 due to etching deposition can be effectively prevented.

It should be noted that if, as described hereinabove, the contact hole is formed in such a way that the tungsten film 17 is exposed in the bottom portion of the contact hole 17a, in some cases an etching reactant (for example tungsten fluoride) may be generated as a result of a reaction between the tungsten film 17 and the etching gas. However, reactants of the tungsten film 17 and the etching gas readily sublimate and are unlikely to cause etching deposition, and therefore even if reactants are generated, problems such as an increase in the contact resistance do not occur.

Further, because the first part 23a of the embedded gate electrodes 23 and the embedded wiring lines 22 is provided with the tungsten film 17, it is higher than the second part 23b. The aspect ratio of the contact hole 17a can thus be reduced. Therefore the occurrence of lost-contact failures can be effectively prevented even if the contact plug 57 is formed at the same time as the capacitor contact plugs 41 in the memory cell region 60 and other contact plugs in the peripheral circuit region 61. It is consequently possible to provide a semiconductor device having an improved yield and improved device characteristics, and a method of manufacturing the same.

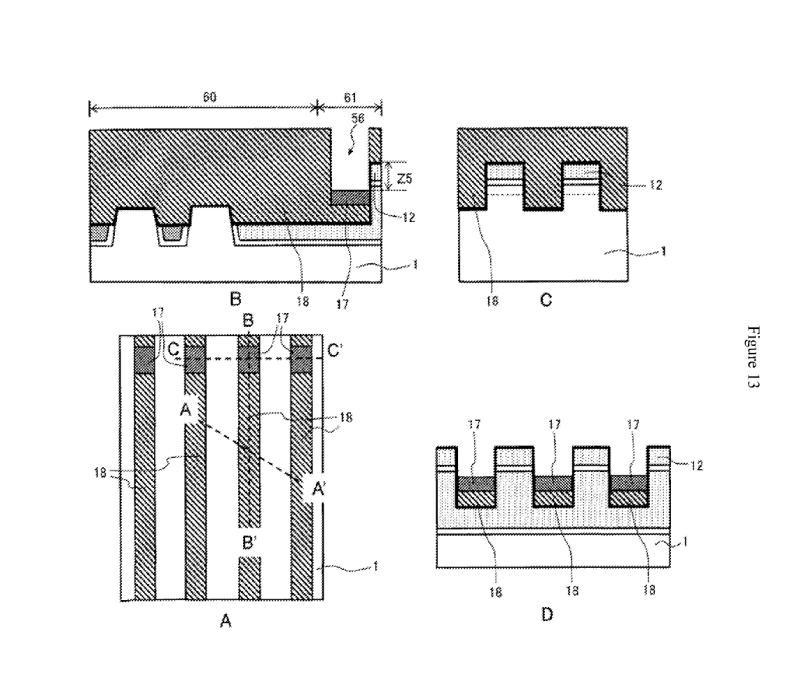

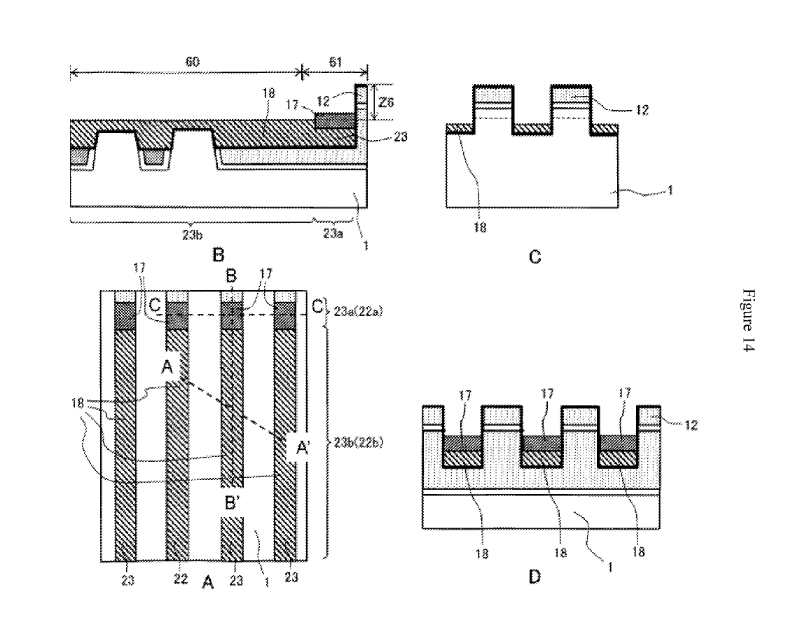

It should be noted that in the step of etching back the tungsten film 17 in FIG. 13 and the step of etching back the titanium nitride film 18 in FIG. 14, discussed hereinafter, the amount of etch-back of the tungsten film 17 and the titanium nitride film 18 can be set freely to any amount. The height of the outermost surface of the tungsten film 17 in the first part 23a and the height of the outermost surface of the titanium nitride film 18 in the second part 23b can thus be controlled. By controlling the heights of the outermost surfaces of the first part 23a and the second part 23b in this way, it is possible to control the aspect ratio of the contact hole 17a.

For convenience of explanation, one embedded gate type transistor having the embedded gate electrode 23 is represented in the active region 1A illustrated in FIG. 2B, but several thousand to several hundreds of thousands of embedded gate type transistors are disposed in the memory cell region of an actual DRAM. Further, although the embedded wiring line 22 illustrated in FIG. 2B has the same structure as the embedded gate electrode 23, it does not function as a word line, but functions to electrically isolate adjacent embedded gate type transistors.

As illustrated in FIG. 2A, the embedded gate type transistor in this example has a structure in which a portion of the embedded gate electrode 23 is embedded in the upper surface of the STI 9 disposed in the direction in which the embedded gate electrode 23 extends. In other words, the height of the upper surface of the STI 9 is arranged in such a way as to be lower than the height of the surface of the silicon substrate 1 (the active region 1A) between adjacent STIs 9. Thus a part in which the STI 9 is embedded by the embedded gate electrode 23, and a saddle-shaped silicon protruding portion 1B which is connected to the bottom surface of the embedded gate electrode 23, with the interposition of the gate insulating film 16, are provided on the upper surface of the silicon substrate 1. It should be noted that the embedded wiring line 22 has the same structure as the embedded gate electrode 23, and therefore the same embedded part of the STI 9 and the saddle-shaped silicon protruding portion 1B are also provided beneath the embedded wiring line 22.

The saddle-shaped silicon protruding portion 1B can be made to function as a channel when the electric potential difference to the source and the drain exceeds a threshold. The embedded gate type transistor in this example is a saddle-fin type transistor, which has a channel region such as the saddle-shaped silicon protruding portion 1B. Using a saddle-fin type transistor as the embedded gate type transistor has the advantage that the ON current is increased.

The configuration above the embedded gate type transistor described hereinabove will now be described with reference to FIG. 2. A plurality of memory cells comprising the abovementioned embedded gate type transistors and the capacitors 48 are provided in the memory cell region of the DRAM 100. The capacitors 48 are crown-type capacitors, formed from a lower electrode 45, a capacitative insulating film 46 and an upper electrode 47. It should be noted that the lower electrodes 45 are in the shape of cylinders having an inner wall surface and an outer wall surface, and the inner wall surface and the outer wall surface face the upper electrode 47 with the interposition of the capacitative insulating film 46. The first impurity-diffused layer 26 of the embedded gate type transistor is connected to a polysilicon film 27 provided on the first impurity-diffused layer 26. Here, the polysilicon film 27, a tungsten silicide layer having a thickness of approximately 5 nm, which is not shown in the drawing, provided on the polysilicon film 27, and a tungsten film 28, form a bit line 30. Further, the upper surface of the bit line 30 is covered by a masking film 29. The second impurity-diffused layer 37 of the embedded gate type transistor is connected to the lower electrode 45 by way of the capacitor contact plug 41 provided on the second impurity-diffused layer 37, and the capacitor contact pad 42a. Here, the capacitor contact plug 41 is formed from a polysilicon film containing an impurity. The capacitor contact pad 42a is provided in order to ensure an alignment margin between the capacitor 48 and the capacitor contact plug 41, and therefore the capacitor contact pad 42a does not need to cover the upper surface of the capacitor contact plug 41, and it is sufficient for it to be located on and connected to at least a portion of the capacitor contact plug 41.

The bit line 30 and the silicon nitride film 20 are covered by an insulating film 31, and the insulating film 31 is further covered by an interlayer insulating film 33 comprising an SiO₂ film containing B (boron) and P (phosphorus), in other words a BPSG (Boron Phosphorus Silicate Glass) film. A stopper film 43 is provided on the interlayer insulating film 33 in such a way as to cover the capacitor contact pad 42a and the wiring line layer 42b. The lower electrode 45 is provided in such a way as to penetrate through a portion of the stopper film 43 and come into contact with the capacitor contact pad 42a. The capacitative insulating film 46 and the upper electrode 47 are provided successively on the exposed inner wall surface and outer wall surface of the lower electrode 45. The lower electrode 45, the capacitative insulating film 46 and the upper electrode 47 form the crown-type capacitor 48.

The upper electrode 47 is covered by an interlayer insulating film 49. A contact plug 50 is provided in the interlayer insulating film 49, and an upper metal wiring line 51 is provided on the upper surface of the interlayer insulating film 49. The upper electrode 47 of the capacitor 48 is connected to the upper metal wiring line 51 by way of the contact plug 50. The upper metal wiring line 51 and the interlayer insulating film 49 are covered by a protective film 52.

It should be noted that a crown-type capacitor 48 in which the inner wall surface and the outer wall surface of the lower electrode 45 are used as electrodes is described as the capacitor in this example, but the capacitor is not limited to this. The capacitor may for example be changed to a cylinder type capacitor in which only the inner wall surface of the lower electrode 45 is used as an electrode. Further, a wiring line layer comprising the upper metal wiring line 51 and the protective film 52 is provided on the capacitor 48, with the interposition of the interlayer insulating film 49. In this example a single-layer wiring line structure having one wiring line layer is described, as one example, but it is not limited to this. This may, for example, be changed to a multilayer wiring-line structure formed from a plurality of wiring lines and interlayer insulating films.

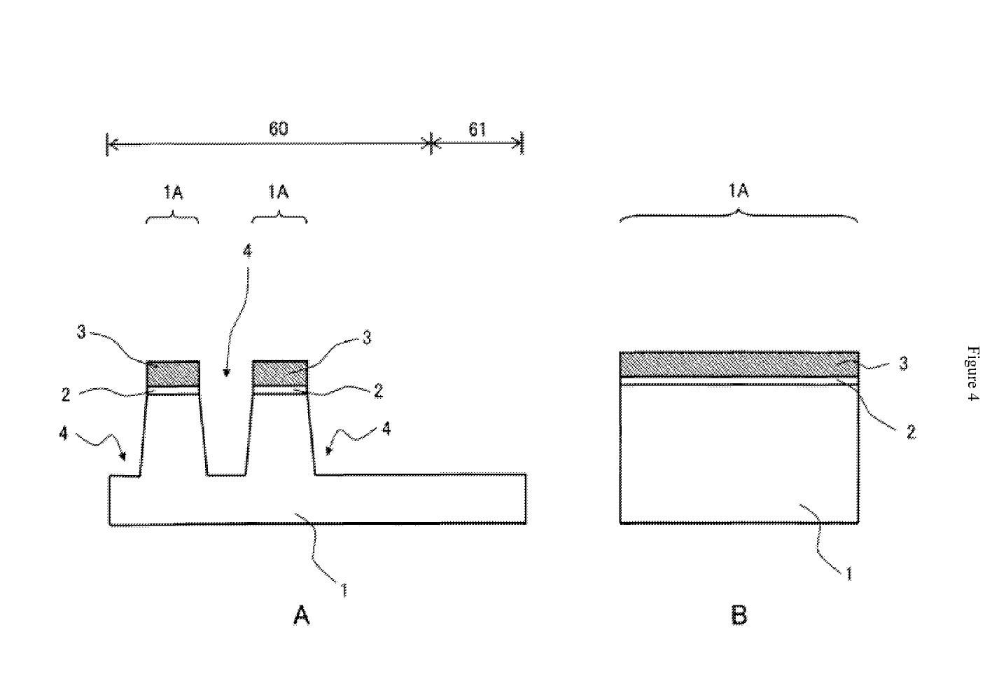

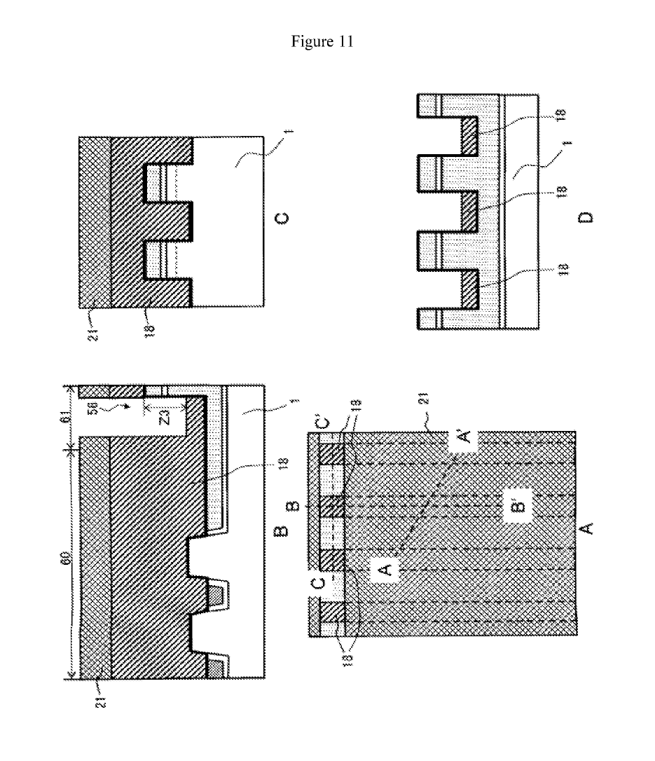

A method of manufacturing the semiconductor device in this example will now be described with reference to FIGS. 2 and 4 to 24. It should be noted that in FIGS. 4 to 10 and 16 to 24, Figure A is a drawing corresponding to the B-W cross-section in FIG. 1B, and Figure B is a drawing corresponding to the A-N cross-section in FIG. 1B. Further, in FIGS. 11 to 15, Figure A is a plan view, and Figure B, Figure C and Figure D respectively represent the B-B′ cross-section, the A-N cross-section and the C-C cross-section in Figure A. The gate insulating film 16 is omitted from FIG. 11A. FIGS. 13A, 14A and 15A mainly illustrate only the embedded gate electrodes 23 and the embedded wiring lines 22, and other structures are omitted.

As illustrated in FIG. 4, the sacrificial film 2, which is a silicon dioxide film (SiO₂) formed by thermal oxidation, and the masking film 3, which is a silicon nitride film (Si₃N₄)formed by thermal CVD (Chemical Vapor Deposition), are deposited successively onto the p-type silicon substrate 1. Next, the masking film 3, the sacrificial film 2 and the silicon substrate 1 are patterned using photolithography and dry etching to form the element isolation grooves 4 (trenches), for demarcating the active regions 1A, in the silicon substrate 1. The top of the silicon substrate 1 which will form the active regions 1A is covered by the masking film 3.

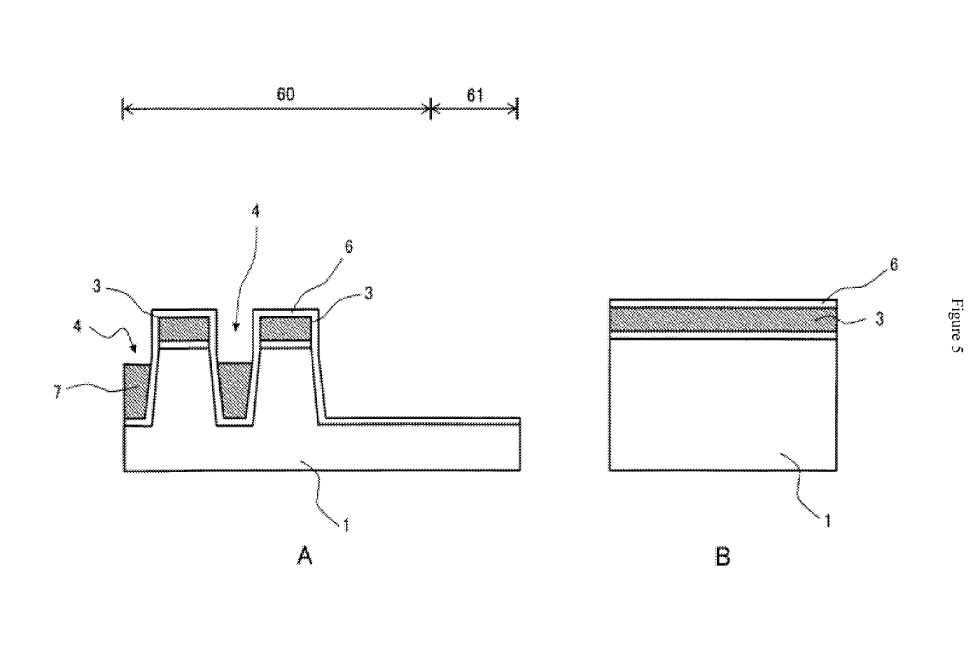

As illustrated in FIG. 5, the insulating film 6, which is a silicon dioxide film, is formed on the outer surfaces of the silicon substrate 1 and the masking film 3 by thermal oxidation. Then the insulating film 7, which is a silicon nitride film, is deposited by thermal CVD in such a way as to fill the interiors of the element isolation grooves 4 in the memory cell region 60, after which it is etched back such that the insulating film 7 remains only in the interiors of the element isolation grooves 4 in the memory cell region 60, and the insulating film 7 in the peripheral circuit region 61 is removed. Wet etching using heated phosphoric acid is employed for the etching back at this time. Further, at this time, the wide element isolation grooves 4 in the peripheral circuit region 61 are not completely filled by the insulating film 7, and are readily removed by wet etching.

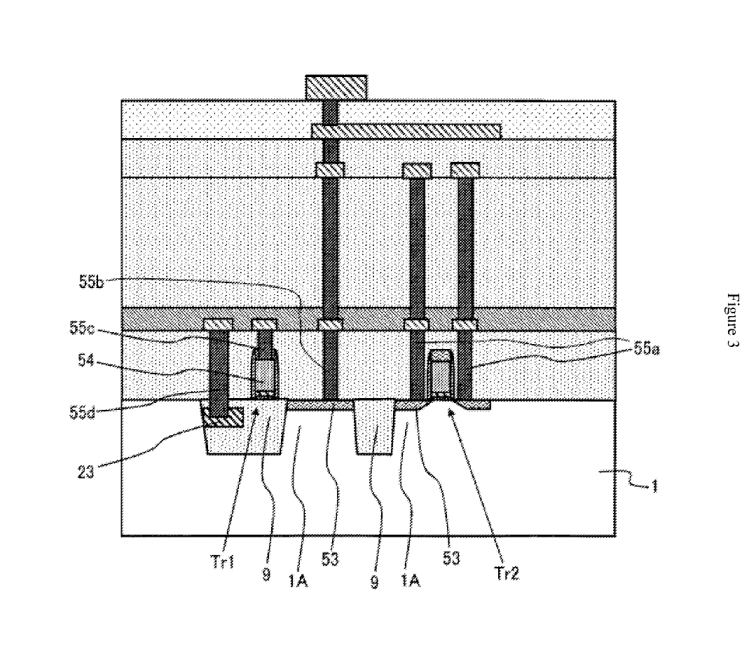

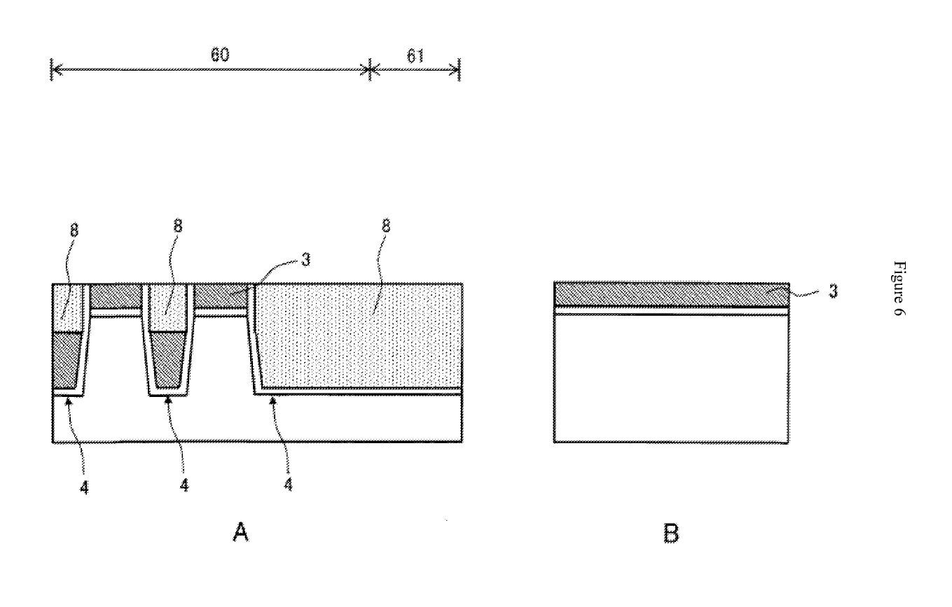

As illustrated in FIG. 6, the embedded film 8, which is a silicon dioxide film, is deposited by plasma CVD in such a way as to fill the interiors of the element isolation grooves 4, after which the surface of the embedded film 8 is planarized by performing a CMP (Chemical Mechanical Polishing) process until the masking film 3 formed in FIG. 3 is exposed.

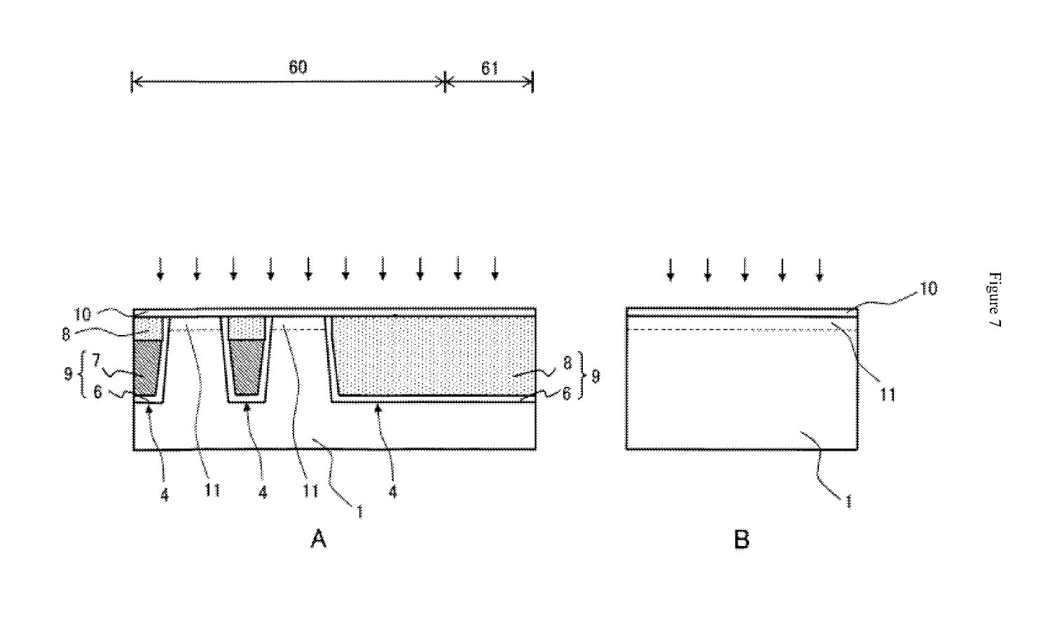

As illustrated in FIG. 7, the masking film 3 and the sacrificial film 2 are removed by wet etching to expose a portion of the silicon substrate 1. Further, the embedded film 8 at the surface of the element isolation grooves 4 is made to be in substantially the same position as the exposed surface of the silicon substrate 1. By means of the processes described hereinabove, the STIs 9 comprising the insulating films 6 and 7, and the STIs 9 comprising the insulating films 6 and 8 are formed. After the STIs 9 have been formed, the sacrificial film 10, which is a silicon dioxide film, is formed on the surface of the silicon dioxide film 1 by thermal oxidation. N-type low-concentration impurity-diffused layers 11 are then formed by implanting a low-concentration n-type impurity (phosphorus or the like) into the silicon substrate 1 by ion implantation. The low-concentration impurity-diffused layers 11 function as portions of the source/drain (S/D) regions of the transistor.

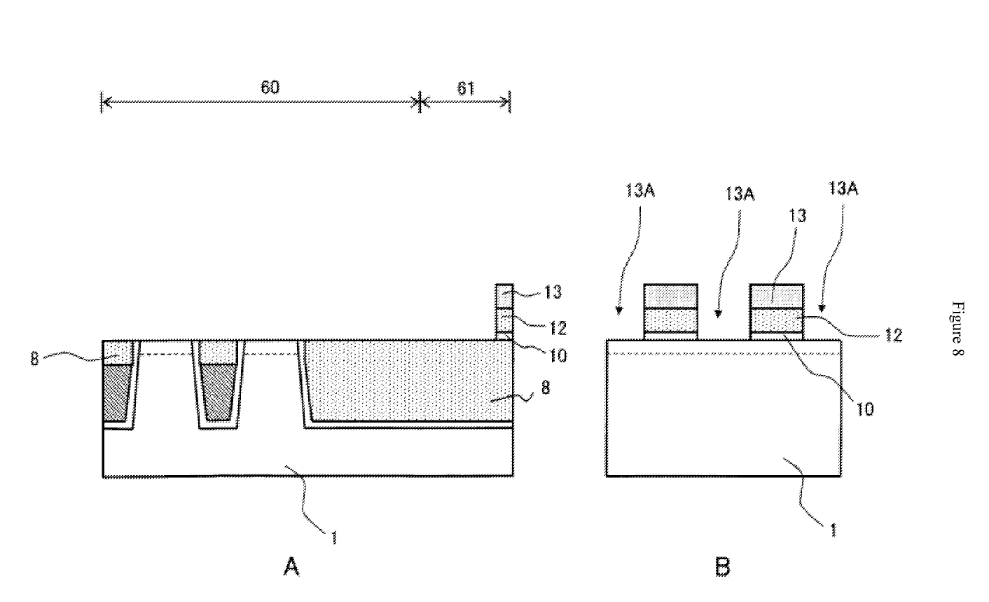

As illustrated in FIG. 8, the lower-layer masking film 12, which is a silicon dioxide film, is deposited on the sacrificial film 10 by CVD, and an upper-layer masking film 13, which is an amorphous carbon film, is then deposited on the lower-layer masking film 12 by plasma CVD. Open portions 13A are then formed by dry etching the upper-layer masking film 13 and the lower-layer masking film 12 to expose portions of the silicon substrate 1. The embedded film 8 is also etched at this time, but dry etching is performed in a condition in which the upper-layer masking film 13 and the lower-layer masking film 12 have etching selectivity relative to the embedded film 8. The embedded film 8 is therefore only very slightly etched.

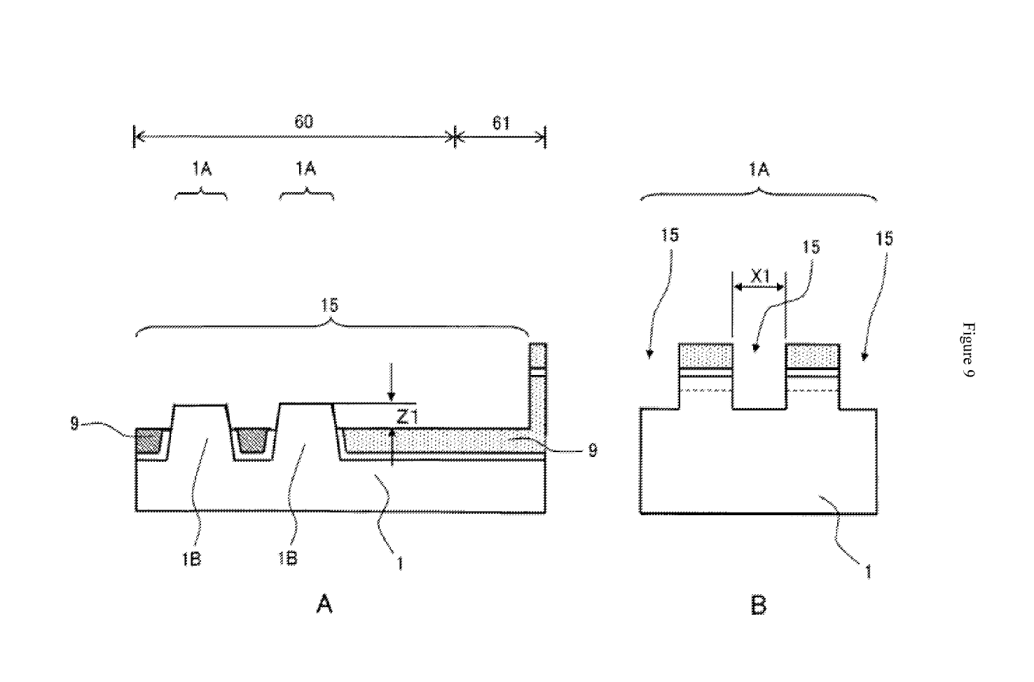

As illustrated in FIG. 9, after removing the upper-layer masking film 13, the silicon substrate 1 exposed through the open portions 13A is etched by dry etching to form the embedded gate electrode grooves (trenches) 15 having a width X1 of 35 nm. This dry etching is performed by reactive ion etching (RIE) using inductively coupled plasma (ICP), with a bias power of 100 to 300 W and a pressure of 3 to 10 Pa, using tetrafluoromethane (CF₄), sulfur hexaflouride (SF₆), chlorine (Cl₂) and helium (He) as process gases. The embedded gate electrode grooves 15 are formed as a line-shaped pattern extending in a direction intersecting the active regions 1A and the peripheral circuit regions 61. When the embedded gate electrode grooves 15 are being formed, the STIs 9 are etched to a greater depth than the surfaces of the silicon protruding portions 1B. By means of this etching, the saddle-shaped silicon protruding portions 1B, the height Z1 of which from the upper surface of the STI 9 is 55 nm, remain. The saddle-shaped silicon protruding portions 1B function as the channel regions of the transistors.

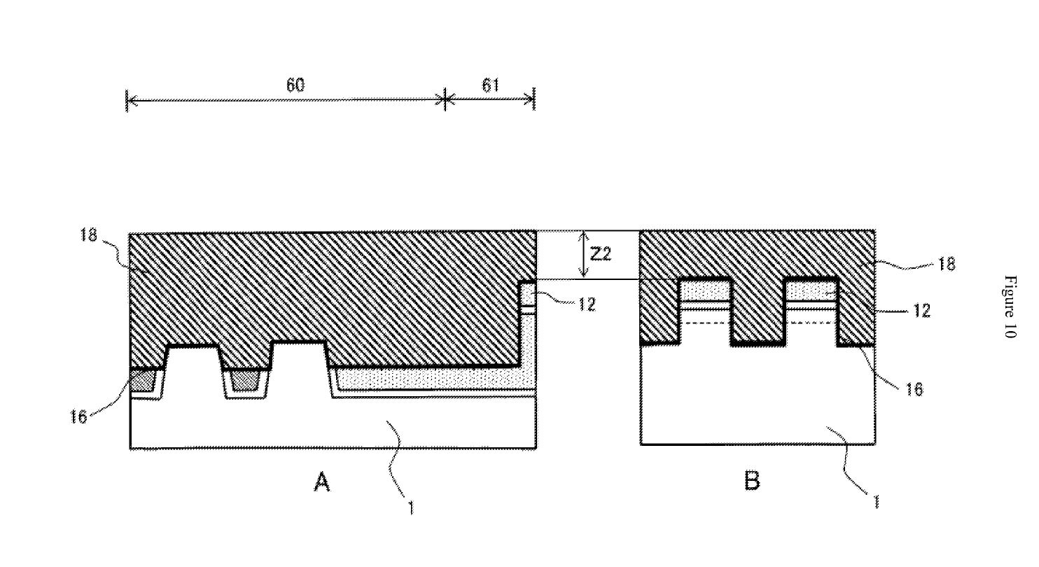

The gate insulating film 16 is formed, as illustrated in FIG. 10. A silicon dioxide film formed by thermal oxidation can, for example, be used as the gate insulating film 16. The titanium nitride (TiN) film 18 is then deposited by CVD. The titanium nitride film 18 is formed to a thickness such that the height Z2 from the outermost surface of the lower-layer masking film 12 to the upper surface of the titanium nitride film 18 is 60 nm.

As illustrated in FIG. 11, a photoresist pattern 21 exposing a portion of the peripheral circuit region 61 is formed on the silicon substrate 1. There is no particular restriction to the planar shape of the photoresist pattern 21, provided that it is a shape having openings in the regions in which the contact holes 17a in the peripheral circuit region 61 are to be formed. The upper portion of the titanium nitride film 18 located in the peripheral circuit region 61 is removed by dry etch-back using the photoresist pattern 21 as a mask, in such a way that the depth Z3 from the outermost surface of the lower-layer masking film 12 is 40 nm, to form openings 56.

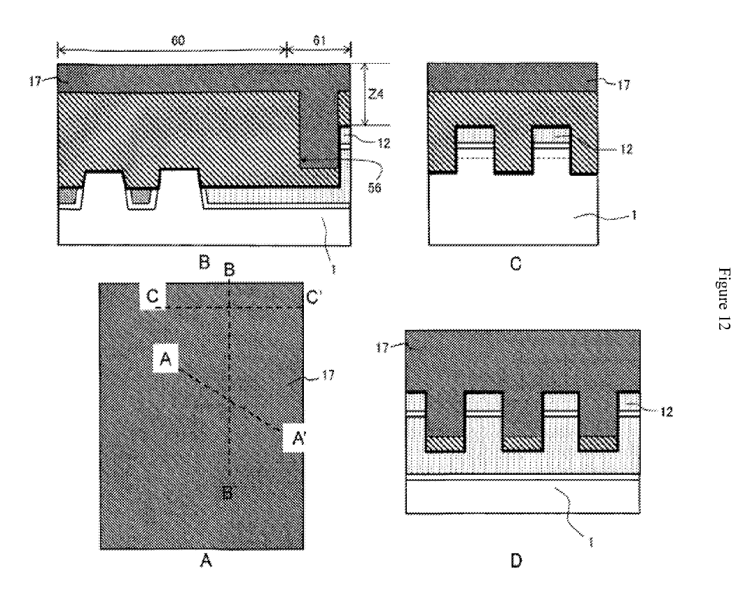

After removing the photoresist pattern 21, the tungsten film 17 (first metal film) is formed over the entire surface of the silicon substrate 1, as illustrated in FIG. 12. At this time, the tungsten film 17 is formed in such a way that the height Z4 from the outermost surface of the lower-layer masking film 12 to the upper surface of the tungsten film 17 is 40 nm, as illustrated in FIG. 12B.

As illustrated in FIG. 13, the upper portion of the tungsten film 17 is removed by dry etching the tungsten film 17 back under conditions having etching selectivity relative to the titanium nitride film 18, in such a way that the height Z5 from the upper surface of the tungsten film 17 located in the peripheral circuit region 61 to the outermost surface of the lower-layer masking film 12 is 20 nm. The tungsten film 17 formed on the titanium nitride film 18, other than in the openings 56, is thus removed. It should be noted that there is no particular restriction to the thickness of the tungsten film 17 after etching back, provided that it is a thickness whereby the upper surface of the tungsten film 17 is lower than the outermost surface of the silicon substrate 1. However, if the tungsten film 17 is thin, the effect of preventing lost-contact failures during formation of the contact plugs 57, discussed hereinafter, is reduced. It is therefore preferable to control the thickness of the tungsten film 17 in such a way that the height between the outermost surface of the tungsten film 17 and the outermost surface of the silicon substrate 1 is approximately 10 nm. The thickness of the tungsten film 17 can be controlled by adjusting the depth of the opening 56 in the step in FIG. 13, and adjusting the amount of etch-back of the tungsten film 17, for example.

As illustrated in FIG. 14, the titanium nitride film 18 is dry etched back under conditions having etching selectivity relative to the tungsten film 17. By this means, the upper portion of the titanium nitride film 18 is removed in such a way that the height Z6 from the upper surface of the titanium nitride film 18 to the outermost surface of the lower-layer masking film 12 is 60 nm. The embedded gate electrodes 23 provided with the second parts 23b comprising a single-layer film of the titanium nitride film 18, in the memory cell region 60, and the first parts 23a, in which the tungsten film 17 is formed on the titanium nitride film 18, in portions of the peripheral circuit region 61, are thus formed. The embedded wiring lines 22 provided with second parts 22b comprising a single-layer film of the titanium nitride film 18, in the memory cell region 60, and first parts 22a, in which the tungsten film 17 is formed on the titanium nitride film 18, in portions of the peripheral circuit region 61, are formed in the same way.

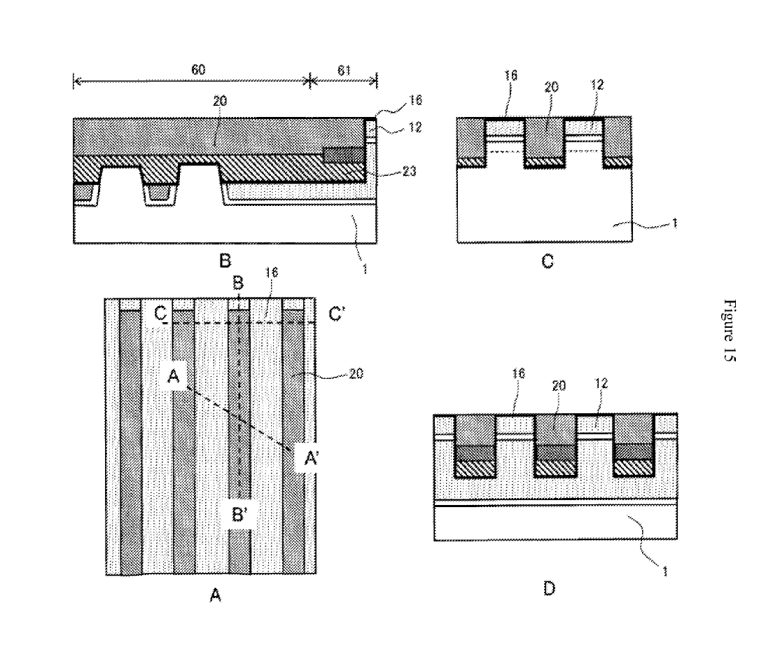

As illustrated in FIG. 15, the silicon nitride film 20 is formed on the silicon substrate 1 in such a way as to cover the lower-layer masking film 12 and the gate insulating film 16. Then, by etching back the silicon nitride film 20, the upper surface of the silicon nitride film 20 is made to be at substantially the same height as the gate insulating film 16 on the lower-layer masking film 12. The upper surfaces of the embedded gate electrodes 23 and the embedded wiring lines for element isolation 22 are thus insulated.

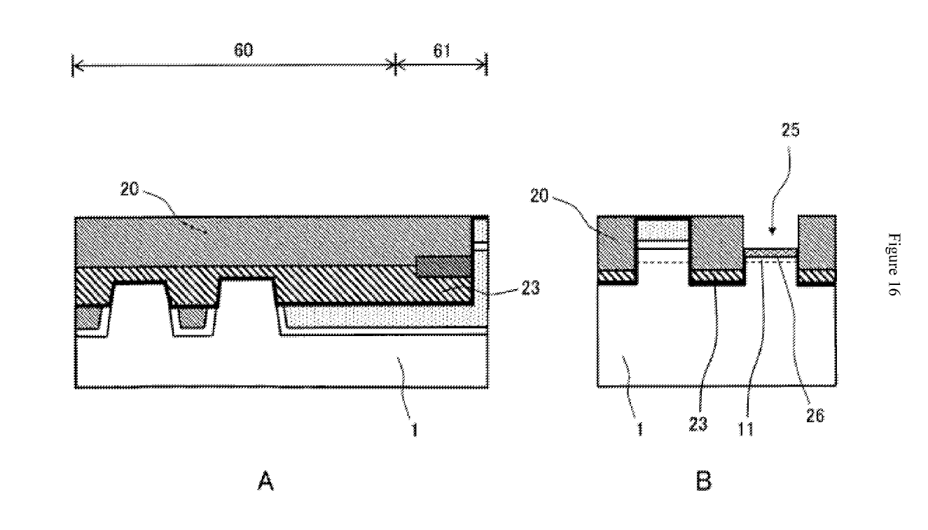

As illustrated in FIG. 16, a portion of the silicon nitride film 20 is removed by photolithography and dry etching, to form bit contact openings 25 which expose the low-concentration impurity-diffused layer 11. The surface of the silicon substrate 1 is exposed in the sections in which the bit contact openings 25 and the active regions 1A overlap. After the bit contact openings 25 have been formed, an n-type impurity (arsenic or the like) is ion-implanted into the bottom portions of the bit contact openings 25 to form the n-type first impurity-diffused layers 26 in the vicinity of the surface of the silicon substrate 1. The n-type first impurity-diffused layers 26 that are formed function as the source/drain of the transistor.

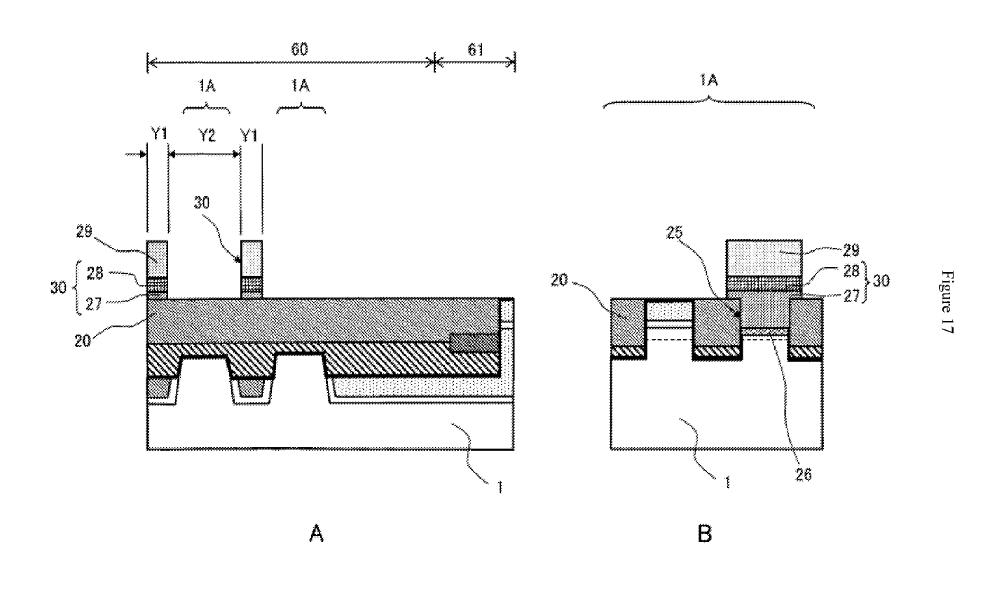

As illustrated in FIG. 17, the polysilicon film 27 containing an n-type impurity (phosphorus or the like), formed by thermal CVD, the tungsten (W) film 28, and the masking film 29, which is a silicon nitride film formed by plasma CVD, are successively deposited in such a way as to cover the first impurity-diffused layer 26 and the silicon nitride film 20. At this time, a tungsten silicide layer having a thickness of 5nm, which is not shown in the drawing, is formed at the interface between the polysilicon film 27 and the tungsten (W) film 28. A laminated film comprising the polysilicon film 27, the tungsten silicide layer, the tungsten film 28 and the masking film 29 is patterned in a line shape, to form the bit lines 30 formed from the polysilicon film 27, the tungsten silicide layer and the tungsten film 28. The width Y1 and the spacing Y2 of the bit lines 30 are respectively 50 nm. The bit lines 30 are formed as a pattern extending in a direction that intersects the embedded gate electrodes 23. In FIG. 1B, the bit lines 30 are illustrated in the shape of straight lines orthogonal to the embedded gate electrodes 23, but they may be disposed with a partially curved shape. The polysilicon film 27 which forms the lower layer of the bit line 30 is connected to the first impurity-diffused layer 26 (one of the source region and the drain region) in the part of the silicon surface that is exposed within the bit contact hole 25.

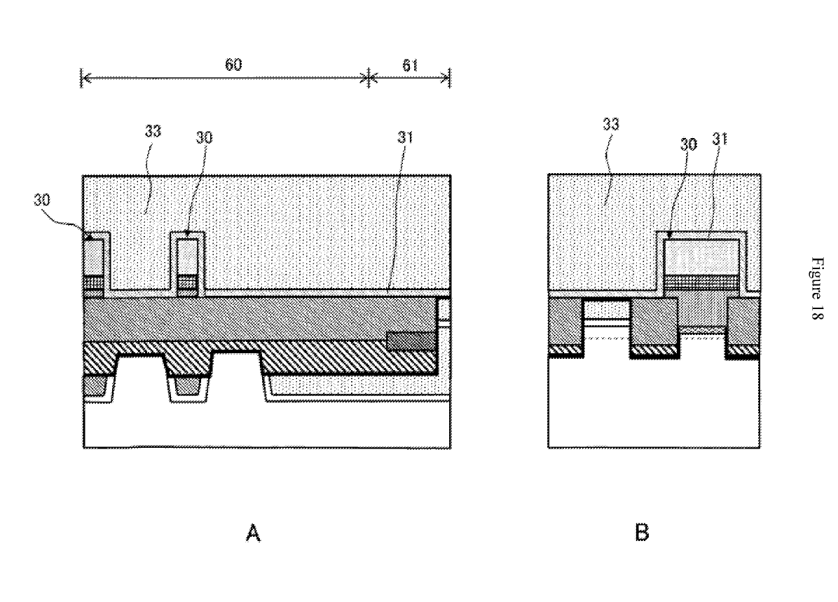

As illustrated in FIG. 18, the insulating film 31, which is a silicon nitride film formed by thermal CVD, is formed in such a way as to cover the side surfaces of the bit lines 30. An SiO₂ film containing B (boron) and P (phosphorus), in other words a BPSG (Boron Phosphorus Silicate Glass) film, is then deposited in such a way as to cover the insulating film 31 and the bit lines 30. The interlayer insulating film 33 is then formed by performing a reflow process.

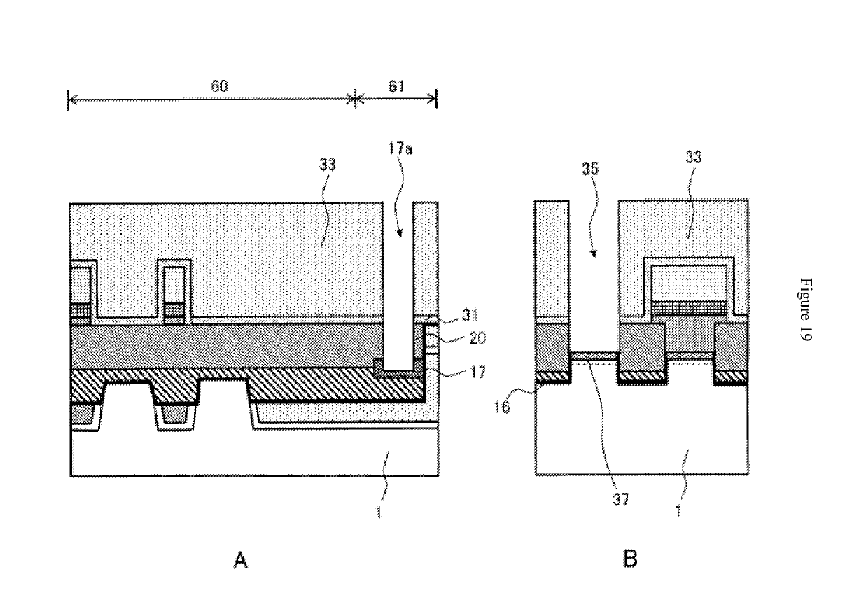

As illustrated in FIG. 19, the capacitor contact holes 35 penetrating through the interlayer insulating film 33, the silicon nitride film 31, the gate insulating film 16, the lower-layer masking film 12 and the sacrificial film 10 to expose the silicon substrate 1, and the contact holes 17a penetrating through the interlayer insulating film 33 and the silicon nitride films 31 and 20 to expose the tungsten film 17 are formed using photolithography and dry etching. The n-type second impurity-diffused layers 37 are formed in the vicinity of the surface of the silicon substrate 1 by ion implantation of an n-type impurity (phosphorus or the like) into the silicon substrate 1. The n-type second impurity-diffused layers 37 that are formed function as the source/drain of the transistor.

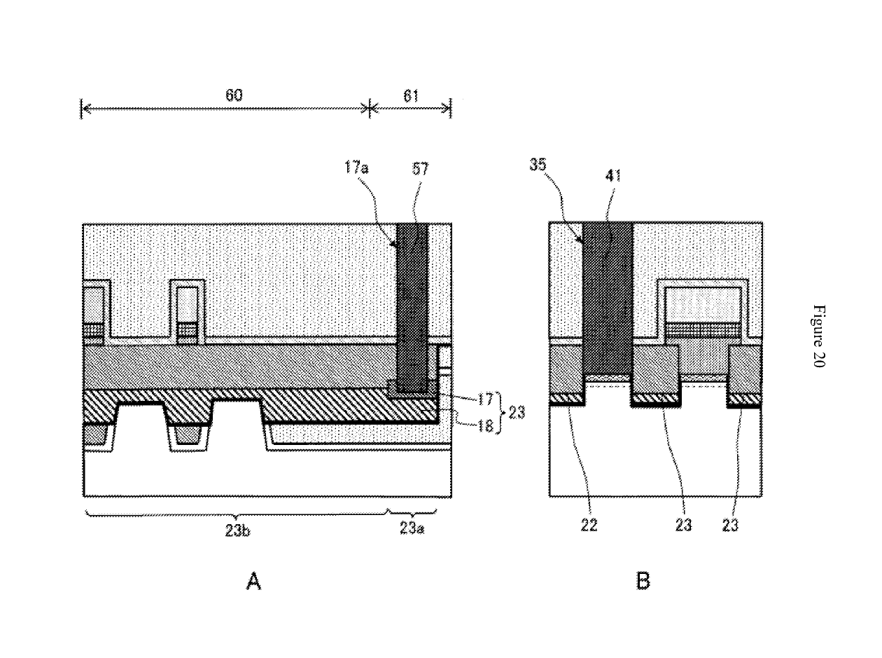

As illustrated in FIG. 20, a polysilicon film containing phosphorus is deposited inside the capacitor contact holes 35 and the contact holes 17a by thermal CVD. Etch-back is then performed such that the polysilicon film remains only in the capacitor contact holes 35 and the contact holes 17a. The capacitor contact plugs 41 and the contact plugs 57 formed from the polysilicon film are thus formed.

In the method of manufacture in this example, the tungsten film 17 is exposed at the bottom portion of the contact hole 17a when the contact hole 17a is being formed, as described hereinabove. Thus when the contact hole 17a is being formed, it is possible to prevent etching deposition of etching reactants (for example titanium fluoride) resulting from reactions between the etching gas and the titanium nitride film 18. As a result, an increase in the contact resistance between the contact plugs 57 and the embedded gate electrodes 23 and embedded wiring lines 22 due to etching deposition can be effectively prevented. Further, because the first parts 23a (22a) of the embedded gate electrodes 23 and the embedded wiring lines 22 are provided with the tungsten film 17, they are higher than the second parts 23b (22b). The aspect ratio of the contact hole 17a can thus be reduced. Therefore lost-contact failures can be effectively prevented even if the contact plug 57 is formed at the same time as other contact plugs in the peripheral circuit region 61. It is consequently possible to provide a semiconductor device having an improved yield and improved device characteristics, and a method of manufacturing the same.

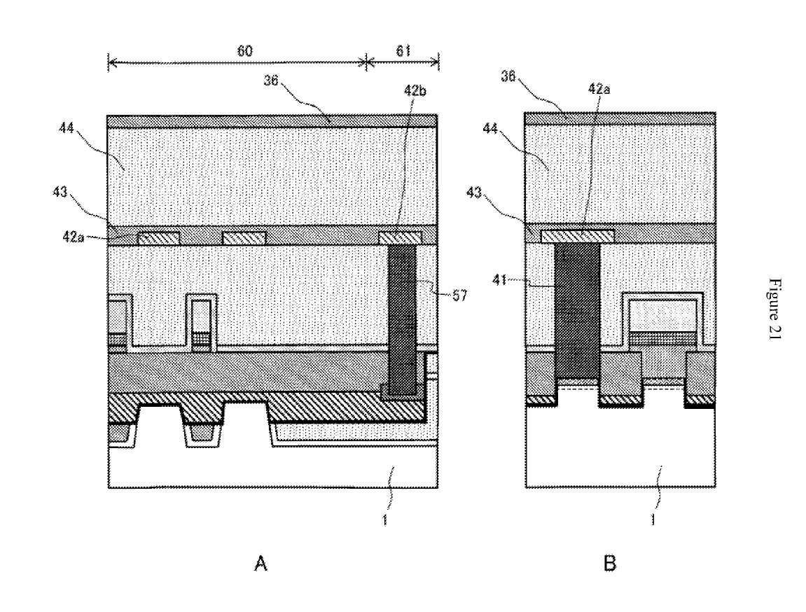

As illustrated in FIG. 21, a tungsten film is formed above the silicon substrate 1 by sputtering. The capacitor contact pads 42a and the wiring line layer 42b are then formed by patterning the laminated film using photolithography and dry etching. Here, the capacitor contact pads 42a are connected to the capacitor contact plugs 41. Further, the wiring line layer 42b is connected to the contact plug 57. The stopper film 43, which is a silicon nitride film formed by thermal CVD, is formed in such a way as to cover the upper surfaces of the capacitor contact pads 42a and the wiring line layer 42b, after which the interlayer insulating film 44, which is a silicon dioxide film, is formed on the stopper film 43 by plasma CVD. A support film 36 comprising a silicon nitride film is formed on the interlayer insulating film 44 by ALD or CVD.

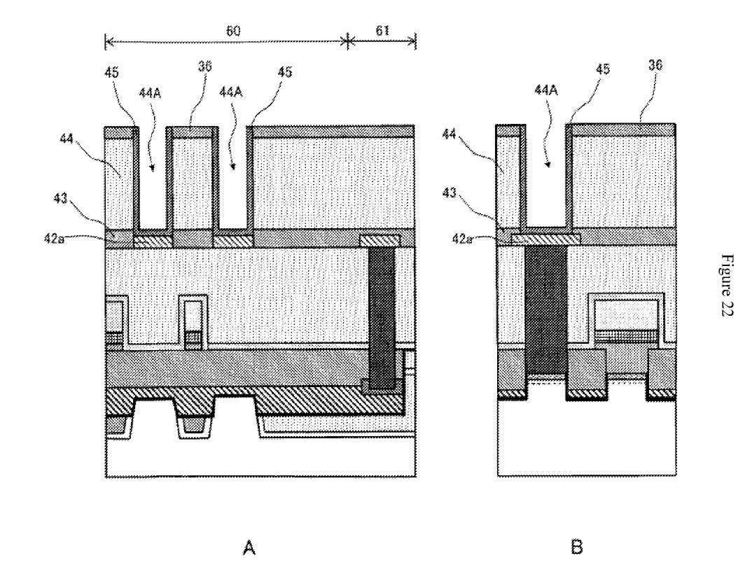

As illustrated in FIG. 22, cylinder holes 44A penetrating through the support film 36, the interlayer insulating film 44 and the stopper film 43 are formed by photolithography and dry etching in such a way as to expose at least a portion of the upper surfaces of the capacitor contact pads 42a. The lower electrodes 45 of the capacitors are then formed from titanium nitride by CVD in such a way as to cover the inner walls of the cylinder holes 44A. The lower surfaces of the lower electrodes 45 in the bottom portions of the cylinder holes 44A are connected to the capacitor contact pads 42a.

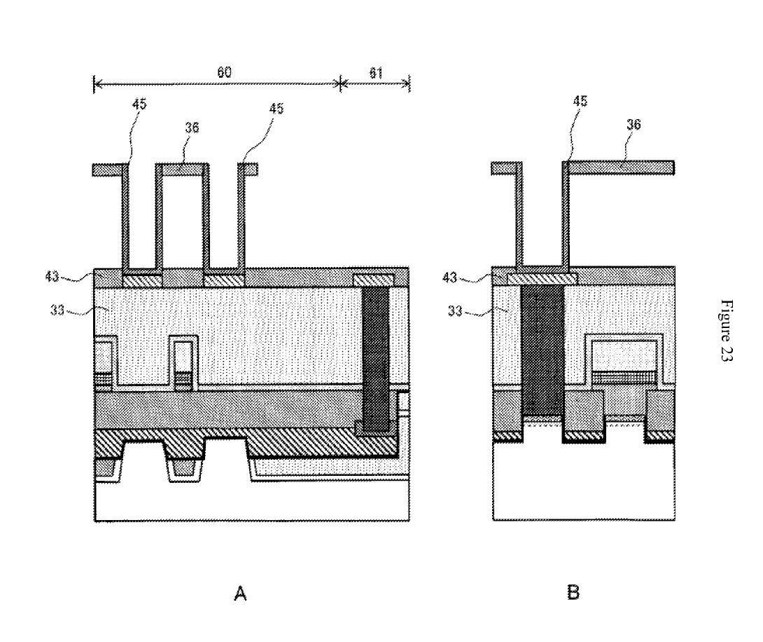

As illustrated in FIG. 23, openings, which are not shown in the drawings, are formed in the support film 36 by photolithography and dry etching. The interlayer insulating film 44 on the memory cell region 60 and the peripheral circuit region 61 in the vicinity of the memory cell region 60 is removed by wet etching using an aqueous solution of dilute hydrofluoric acid. This wet etching exposes the inner wall surfaces and the outer wall surfaces of the lower electrodes 45. Further, the stopper film 43 prevents the interlayer insulating film 33 and the like located in the layers below the stopper film 43 from being wet etched.

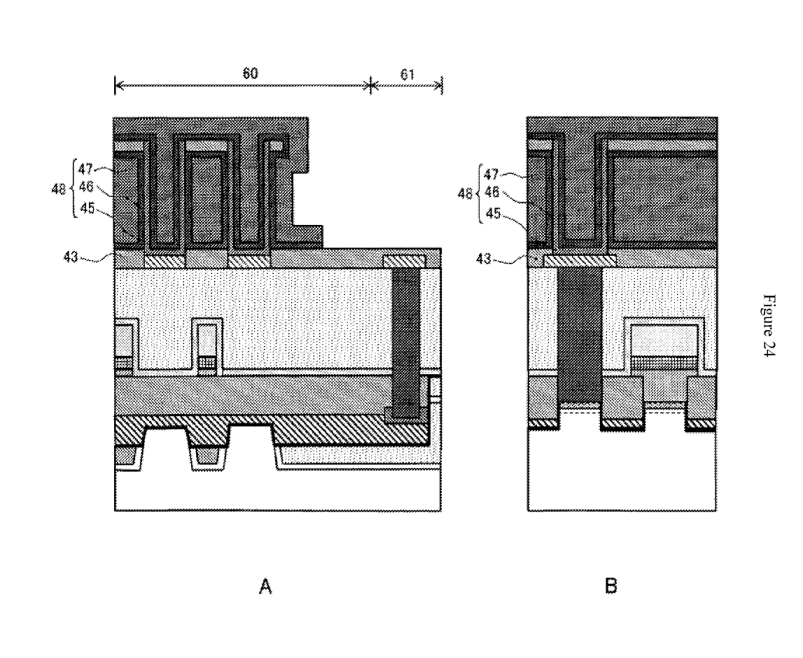

As illustrated in FIG. 24, the capacitative insulating film 46 is formed by ALD in such a way as to cover the exposed inner wall surfaces and outer wall surfaces of the lower electrodes 45, after which the titanium nitride upper electrodes 47 of the capacitors are formed by CVD. Here, zirconium oxide (ZrO₂), aluminum oxide (Al₂O₃), hafnium oxide (HfO₂) or laminated films thereof may be used as the capacitative insulating film 46. The capacitative insulating film 46 and the upper electrode 47 located on the stopper film 43 in the peripheral circuit region 61 and the memory cell region 60 in the vicinity thereof are then removed by lithography and dry etching. The capacitors 48 comprising the lower electrodes 45, the capacitative insulating films 46 and the upper electrodes 47 are thus formed.

As illustrated in FIGS. 2A and 2B, the interlayer insulating film 49, which is a silicon dioxide film formed by plasma CVD, is formed in such a way as to cover the upper electrodes 47, after which contact holes (which are not shown in the drawings) are formed in the interlayer insulating film 49 by photolithography and dry etching. The contact holes are then filled with tungsten by CVD, after which excess tungsten on the upper surface of the interlayer insulating film 49 is removed by CMP to form the contact plugs 50. Aluminum (Al), copper (Cu) or the like is then deposited on the upper surface of the interlayer insulating film 49 and is then patterned to form the upper metal wiring lines 51. At this time the upper metal wiring lines 51 are connected to the upper electrodes 47 by way of the contact plugs 50. The protective film 52 is then formed in such a way as to cover the upper metal wiring lines 51, thereby completing the memory cells of the DRAM 100.

In the abovementioned example, the tungsten film 17 is formed as the first metal film. However, there is no particular restriction to the material used for the first metal film provided that it is a material with which etching deposition of etching reactants does not occur when the contact holes 17a are being formed. A tungsten film, a molybdenum film or a ruthenium film is preferably used as the first metal film. Further, a tungsten nitride film, a molybdenum nitride film or a ruthenium nitride film is also preferably used as the first metal film. When these films are used, etching deposition of etching reactants does not occur when the contact holes 17a are being formed, and an increase in the contact resistance between the embedded gate electrodes 23 and the embedded wiring lines 22, and the contact plugs 57, can be prevented. Further, another film such as a tungsten nitride film, a molybdenum nitride film or a ruthenium nitride film may also be formed between the first metal film and the titanium nitride film 18. In this case the first part is preferably a laminated film comprising a tungsten film/a tungsten nitride film/a titanium nitride film, a molybdenum film/a molybdenum nitride film/a titanium nitride film, or a ruthenium film/a ruthenium nitride film/a titanium nitride film.

(Second Example)

This example differs from the first example in that, in the embedded gate electrodes 23 and the embedded wiring lines 22, the width W₁ of the part in contact with the contact plugs 57 (the first part provided with the titanium nitride film 18 and the tungsten film 17) is greater than the width W₂ of the second part comprising the single-layer film of the titanium nitride film 18. Other structures in the semiconductor device in this example are the same as in the semiconductor device in the first example, and therefore the description here focuses on the structures that differ from the first example.

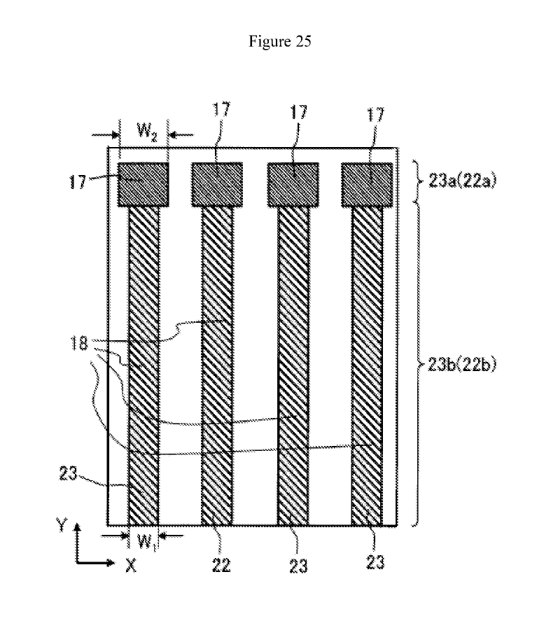

FIG. 25 is a plan view illustrating the semiconductor device in this example, illustrating only the embedded gate electrodes 23 and the embedded wiring lines 22, other structures being omitted. Further, the X-direction and the Y-direction in FIG. 25 represent the same directions as the X-direction and the Y-direction in FIG. 1 in the first example

As illustrated in FIG. 25, in the embedded gate electrodes 23 in this example the width W₂ of the first part 23a in the X-direction (the direction perpendicular to the direction in which the embedded gate electrodes 23 extend) is greater than the width W₁ of the second part 23b in the X-direction (the direction perpendicular to the direction in which the embedded gate electrodes 23 extend). Similarly, in the embedded wiring lines 22, the width W₂ of the first part 22a in the X-direction is greater than the width W₁ of the second part 22b. In the semiconductor device in this example, in addition to the effects in the first example, the following effects can also be exhibited. To elaborate, in the semiconductor device in the first example, in the lithography step when the contact holes 17a are formed, there may be cases in which misalignment occurs, causing the titanium nitride film 18 to be exposed in the bottom portions of the contact holes 17a. In this case, problems occur in that etching deposition of etching reactants occurs during formation of the contact holes 17a, increasing the contact resistance between the embedded gate electrodes 23 and the embedded wiring lines 22, and the contact plugs 57. The abovementioned misalignment occurrences become particularly pronounced if miniaturization of the semiconductor device progresses.

In contrast, in the semiconductor device in this example, the width of the first part 23a (22a) is large, and therefore the alignment margin in the lithography step when the contact holes 17a are formed is large. As a result, an increase in the contact resistance resulting from the abovementioned misalignment can be effectively prevented.

It should be noted that the value of the width W₂ can be set as appropriate in accordance with the width W₁ and the dimensions of other parts of the semiconductor device, for example. For example, if the embedded gate electrode grooves 15 are formed in the shape of a line-and-space pattern, where the width of the line portions (corresponding to the embedded gate electrode grooves 15) is 20 nm and the width of the space portions (corresponding to the regions between the embedded gate electrode grooves 15) is 20 nm, the top diameter of the contact holes 17a is 20 nm, the bottom diameter is 10 nm, and the contact hole 17a alignment capability is ±10 nm, then the value of the widths W₂-W₁ is 10 nm, and the first part is 5 nm wider than the second part on both sides in the width direction. An increase in the contact resistance resulting from misalignment can thus be effectively prevented.

It should be noted that in the second example an example is illustrated in which the width of the first part is greater than the width of the second part, but the length of the first part in the direction in which the embedded gate electrodes 23 and the embedded wiring lines 22 extend (the Y-direction in FIG. 1) may also be increased to increase the alignment margin in the direction of extension.

With regard to the steps for manufacturing the semiconductor device in this example, the semiconductor device in this example can be manufactured using the same steps as in the first example, except that in the step of forming the embedded gate electrode grooves 15 in FIG. 9 in the first example, the embedded gate electrode grooves 15 are formed to a shape corresponding to FIG. 25. To elaborate, in this example the embedded gate electrode grooves 15 are formed in such a way that the width of the part corresponding to the first part is greater than the width of the second part, as seen in a plan view.

(Other Application Examples)

In the abovementioned first and second examples, the semiconductor device and the method of manufacturing the same according to the present invention are described taking a DRAM as an example of a semiconductor device. However, the present invention can also be applied to other semiconductor devices provided with an electrode structure having a first part and a second part (for example PRAMs or ReRAMs).

Further, the single-layer film of the titanium nitride film' set forth in the scope of the patent claims indicates, for example, a single titanium nitride film having a uniform composition and formed using the same deposition method, laminated films comprising a plurality of titanium nitride films each having a mutually different nitrogen content, and laminated films comprising a plurality of titanium nitride films each formed using mutually different deposition methods.

Explanation of the Reference Numbers

1 Silicon substrate

1a Main surface

1A Active region

1B Silicon protruding portion

2 Sacrificial film

3 Masking film

4 Element isolation groove (trench)

6 Insulating film

7 Insulating film

8 Embedded film

9 STI

10 Sacrificial film

11 Low-concentration impurity-diffused layer

12 Lower-layer masking film

13 Upper-layer masking film

13A Open portion

15 Embedded gate electrode groove (trench)

16 Gate insulating film

17 Tungsten film

17a Contact hole

18 Titanium nitride film

20 Silicon nitride film

21 Photoresist pattern

22 Embedded wiring line for element isolation

23 Embedded gate electrode

22a, 23a First part

22b, 23b Second part

25 Bit contact opening

16 First impurity-diffused layer

27 Polysilicon film

28 Tungsten film

29 Masking film

30 Bit line

31 Insulating film

33, 34, 49 Interlayer insulating film

35 Capacitor contact hole

36 Support film

37 Second impurity-diffused layer

41 Capacitor contact plug

42a Capacitor contact pad

42b Wiring line layer

43 Stopper film

44A Cylinder hole

45 Lower electrode

46 Capacitative insulating film

47 Upper electrode

48 Capacitor

50 Contact plug

51 Upper metal wiring line

52 Protective film

53 Impurity-diffused layer

54 Gate electrode

55a, 55b, 55c, 55d Contact plug

56 Opening

57 Contact plug

60 Memory cell region

61 Peripheral circuit region

100 DRAM

Tr1, Tr2 Transistor

1. A semiconductor device comprising:
a silicon substrate;
an embedded gate electrode groove provided in the silicon substrate;
a gate insulating film provided on an inner wall of the embedded gate electrode groove;
an embedded gate electrode which is provided on the gate insulating film in such a way as to fill the embedded gate electrode groove, and which comprises a first part comprising a titanium nitride film with a first metal film thereon, and a second part comprising a single-layer film of the titanium nitride film but not including the first metal film; and
a contact plug which is electrically connected to the first metal film which is a constituent of the first part of the embedded gate electrode.

2. The semiconductor device of claim 1, wherein the first metal film is a tungsten film, a molybdenum film, or a ruthenium film.

3. The semiconductor device of claim 2, wherein the first part is additionally provided, between the first metal film and the titanium nitride film, with a tungsten nitride film, a molybdenum nitride film, or a ruthenium nitride film.

4. The semiconductor device of claim 1, wherein the first metal film is a tungsten nitride film, a molybdenum nitride film, or a ruthenium nitride film.

5. The semiconductor device of claim 1, wherein the height of the outermost surface of the embedded gate electrode is in a position that is lower than the height of the outermost surface of the silicon substrate.

6. The semiconductor device of claim 1, wherein, in a direction perpendicular to the direction in which the embedded gate electrode extends, the width of the first part is greater than the width of the second part.

7. The semiconductor device of claim 1, comprising an active region and an element isolation region provided in such a way as to demarcate the active region, and wherein the embedded gate electrode extends across the element isolation region and the active region.

8. The semiconductor device of claim 7, comprising:
a first and a second impurity-diffused layer on both sides, sandwiching the embedded gate electrode groove, within the active region;
a bit line which is electrically connected to the first impurity-diffused layer; and
a capacitor which is electrically connected to the second impurity-diffused layer,
wherein the second part of the embedded gate electrode, the gate insulating film, the first and second impurity-diffused layers and the capacitor form a memory cell, and the semiconductor device is provided with a memory cell region comprising a plurality of the memory cells.

9. The semiconductor device of claim 8, comprising a peripheral circuit region provided in such a way as to surround the memory cell region, wherein the first part of the embedded gate electrode is located in the peripheral circuit region.

10. The semiconductor device of claim 9, comprising a wiring line layer on the peripheral circuit region, wherein the wiring line layer is electrically connected to the upper surface of the contact plug.

11. A method of manufacturing a semiconductor device, comprising:
forming an embedded gate electrode groove in a silicon substrate;
forming a gate insulating film on an inner wall of the embedded gate electrode groove;
forming a titanium nitride film on the gate insulating film in such a way as to fill the embedded gate electrode groove;
of etching back a portion of the titanium nitride film to cause its upper surface to recede;
forming a first metal film on the receded upper surface of the titanium nitride film;
forming a first part comprising the titanium nitride film and the first metal film by etching back the first metal film to cause its upper surface to recede;
forming a second part comprising a single-layer film of the titanium nitride film by etching back the exposed part of the titanium nitride film to cause its upper surface to recede; and
forming a contact plug which is electrically connected to the first metal film.

12. The method of claim 11, wherein causing the upper surface of the titanium nitride film to recede comprises protecting the upper surface of the titanium nitride film other than the upper surface of the abovementioned portion using a resist mask.

13. The method of claim 11, wherein the first metal film is a tungsten film, a molybdenum film, or a ruthenium film.

14. The method of claim 11, wherein forming the embedded gate electrode groove comprises forming the embedded gate electrode groove in such a way that in a direction perpendicular to the direction in which the embedded gate electrode groove extends, the width of a region in which the first part is to be formed is greater than the width of a region in which the second part is to be formed.

15. The method of claim 11, wherein causing the upper surface of the titanium nitride film to recede comprises etching a portion of the titanium nitride film back in such a way that the upper surface of the abovementioned portion of the titanium nitride film is in a position that is lower than the outermost surface of the silicon substrate.

16. The method of claim 11, wherein forming the first part comprises etching the first metal film back in such a way that the outermost surface of the first metal film is in a position that is lower than the outermost surface of the silicon substrate.

17. The method of claim 11, wherein forming the second part comprises etching the exposed part of the titanium nitride film back in such a way that the outermost surface of the second part is in a position that is lower than the outermost surface of the silicon substrate.

18. The method of claim 11, comprising, after forming the second part, forming an insulating film in such a way as to fill the embedded gate electrode groove, and etching back the insulating film in such a way that the outermost surface of the insulating film is higher than the outermost surface of the silicon substrate.

19. The method of claim 11 comprising, before the embedded gate electrode groove is formed, forming in the silicon substrate an active region, and an element isolation region demarcating the active region, wherein forming the embedded gate electrode groove comprises forming the embedded gate electrode groove in such a way as to extend across the element isolation region and the active region.

20. The method of claim 19, comprising,
after the embedded gate electrode groove is formed,
forming a first and a second impurity-diffused layer on both sides, sandwiching the embedded gate electrode groove, within the active region;
forming a bit line which is electrically connected to the first impurity-diffused layer; and
forming a capacitor which is electrically connected to the second impurity-diffused layer,
wherein the second part, the gate insulating film, the first and second impurity-diffused layers and the capacitor form a memory cell, and the semiconductor device is provided with a memory cell region comprising a plurality of the memory cells.
